(19) United States
(12) Patent Application Publication
(10) Pub. No.: US 2025/0191174 A1
(43) Pub. Date: Jun. 12, 2025

(54) MANUFACTURING METHOD OF ELECTRONIC DEVICE AND DETECTION DEVICE

(71) Applicant: InnoLux Corporation, Miao-Li County (TW)

(72) Inventors: Hui-Teng LIN, Miao-Li County (TW); Yu-Chen CHOU, Miao-Li County (TW)

(21) Appl. No.: 18/944,552

(22) Filed: Nov. 12, 2024

(30) Foreign Application Priority Data
Dec. 8, 2023 (CN) 202311683954.2

(51) Int. Cl. G06T 7/00; H01L 21/66

(52) U.S. Cl. CPC G06T 7/001; H01L 22/12; G06T 2207/30108

(57) ABSTRACT

A manufacturing method of an electronic device and a detection device are provided. The manufacturing method of the electronic device includes the following steps. An area condition is stored. A plurality of light-emitting modules are provided. A detection process on each light-emitting module is performed, wherein the detection process includes: lighting up a light-emitting module to be tested; capturing an initial image of the light-emitting module to be tested; performing image processing on the initial image to obtain area information; and comparing the area condition with the area information of the light-emitting module to be tested to determine whether the light-emitting module to be tested belongs to a first group of light-emitting modules or a second group of light-emitting modules. A light-emitting module of the first group of light-emitting modules and a display panel are assembled to obtain the electronic device.

### CROSS REFERENCE TO RELATED APPLICATIONS

This application claims priority of China Patent Application No. 202311683954.2, filed on Dec. 8, 2023, the entirety of which is incorporated by reference herein.

### BACKGROUND OF THE INVENTION

### Field of the Invention

The present disclosure relates to electronic devices, and, in particular, to a manufacturing method of electronic device and a detection device.

### Description of the Related Art

Electronic devices that include light-emitting modules (such as tablets, laptops, smartphones, monitors, and televisions) have become indispensable necessities in modern society. With the booming development of such electronic devices, consumers have high expectations regarding the quality, functionality, and price of these products.

In order to ensure the quality of electronic devices, a series of detection processes are generally performed on the light-emitting modules used in electronic devices. In the existing detection process, the light source on the light-emitting module is usually lighted up using control software (e.g., to make the light-emitting unit of the light-emitting module emit light), and an image of the light-emitting module is captured by an image-capturing module. Finally, using manual methods, the operators determine whether the light-emitting module meets standards. However, this method is limited by the differences in experience and visual acuity among different operators, and different types of detections also consume a lot of work time.

Therefore, although the existing manufacturing methods and detection devices of electronic devices have largely met their intended purposes, they do not meet requirements in all respects. Therefore, there are still some problems that need to be overcome regarding the manufacturing method and detection device of the electronic device.

### BRIEF SUMMARY OF THE INVENTION

In some embodiments, a manufacturing method of an electronic device is provided. The manufacturing method of the electronic device includes the following steps. An area condition is stored. A plurality of light-emitting modules are provided. A detection process on each light-emitting module is performed. The detection process includes: lighting up a light-emitting module to be tested; capturing an initial image of the light-emitting module to be tested; performing image processing on the initial image to obtain area information; and comparing the area condition with the area information of the light-emitting module to be tested to determine whether the light-emitting module to be tested belongs to a first group of light-emitting modules or a second group of light-emitting modules. A light-emitting module of the first group of light-emitting modules and a display panel are assembled to obtain the electronic device.

In some embodiments, a detection device used to detect a light-emitting module to be tested is provided. The detection device includes an image-capturing module, a storage module, and a processing module. The image-capturing module is configured to capture an initial image of the light-emitting module to be tested. The storage module is configured to store an area condition. The processing module is configured to receive the initial image of the light-emitting module to be tested captured by the image-capturing module, perform image processing on the initial image to obtain area information, and compare the area condition with the area information to obtain a comparison result to determine whether the light-emitting module to be tested belongs to a first group of light-emitting modules that meet the area condition or a second group of light-emitting modules that do not meet the area condition.

The manufacturing method of an electronic device and the detection device of the present disclosure can be applied in a variety of electronic devices. In order to make the features and advantages of the present disclosure more comprehensible, various embodiments are specially cited hereinafter, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a schematic diagram showing the detection device according to some embodiments of the present disclosure.

FIG. 1B is a schematic diagram showing the electronic device according to some embodiments of the present disclosure.

FIG. 2 is a schematic diagram showing the detection device according to other embodiments of the present disclosure.

FIG. 3 is a schematic diagram showing the operation of the detection device according to some embodiments of the present disclosure.

FIG. 4 is a flowchart showing the manufacturing method of the electronic device according to some embodiments of the present disclosure.

FIG. 5 is a flowchart showing the pre-operations of the image processing according to some embodiments of the present disclosure.

FIG. 6 is a flowchart showing the operations of the image processing according to some embodiments of the present disclosure.

FIGS. 7A to 7C are schematic diagrams showing the different stages of the image processing according to some embodiments of the present disclosure.

FIG. 8 is a flowchart showing the operations of the image processing according to other embodiments of the present disclosure.

FIGS. 9A to 9F are schematic diagrams showing the different stages of the image processing according to other embodiments of the present disclosure.

FIG. 10 is a flowchart showing the operations of the image processing according to further embodiments of the present disclosure.

FIGS. 11A to 11C are schematic diagrams showing the different stages of the image processing according to further embodiments of the present disclosure.

FIG. 12 is a flowchart showing the operations of the image processing according to further embodiments of the present disclosure.

FIGS. 13A to 13D are schematic diagrams showing the different stages of the image processing according to further embodiments of the present disclosure.

### DETAILED DESCRIPTION OF THE INVENTION

In order to make the above objects, features, and benefits of some embodiments of the present disclosure more obvious and understandable, detailed descriptions are given hereinafter with reference to the drawings.

It should be understood that the terms “include” and “comprise” used in the present disclosure are used to indicate the existence of specific technical features, numerical values, method steps, operation processes, elements, and/or components, but do not exclude that more technical features, numerical values, method steps, operation processes, elements, components, or any combination thereof may be added.

The terms such as “first”, “second”, “third”, “fourth”, and the like are used to modify elements and are not used to indicate the priority or precedence relationship therebetween but are used to clearly distinguish elements with the same name.

It should be noted that, in the following embodiments, features in several different embodiments may be replaced, recombined, and bonded to complete other embodiments without departing from the spirit of the present disclosure. The features of the various embodiments can be used in any combination as long as they do not violate the spirit of the present disclosure or conflict with each other.

In the present disclosure, the electronic device may include a display device, a back light device, an antenna device, a sensing device, or a titling device, but the present disclosure is not limited thereto. The electronic device may be a foldable or flexible electronic device. The display device may be a non-self-luminous display device or a self-luminous display device. The antenna device may be a liquid-crystal antenna device or a non-liquid-crystal antenna device. The sensing device may be a sensing device for sensing capacitance, light, heat, or ultrasonic waves, but the present disclosure is not limited thereto. The electronic elements may include passive elements and active elements, such as capacitors, resistors, inductors, diodes, transistors, and the like. The diodes may include light-emitting diodes or photodiodes. The light-emitting diodes may include, for example, organic light-emitting diodes (OLEDs), mini light-emitting diodes (mini LEDs), micro light-emitting diodes (micro LEDs), or quantum dot light-emitting diodes (quantum dot LED), but the present disclosure is not limited thereto. The titling device may be, for example, a display titling device or an antenna titling device, but the present disclosure is not limited thereto. It should be noted that, the electronic device can be any arrangement and combination of the foregoing, but the present disclosure is not limited thereto. The content of the present disclosure will be described hereinafter with an electronic device as a display device or a titling device, but the present disclosure is not limited thereto.

In addition, the shape of the electronic device may be a rectangle, a circle, a polygon, a shape with curved edges, or other suitable shapes. The electronic device may have peripheral systems such as a processing system, a driving system, a control system, a light source system, and a shelf system to support the electronic device.

In some embodiments, additional features may be added to the electronic device of the present disclosure. In some embodiments, some features of the electronic device disclosed herein may be replaced or omitted. In some embodiments, additional operation steps may be provided before, during, and after the manufacturing method of the electronic device. In some embodiments, some of the described operation steps may be replaced or omitted, and the order of some of the described operation steps may be interchangeable. Furthermore, it should be understood that some of the described operation steps may be replaced or deleted for other embodiments of the method. Moreover, in the present disclosure, the number and size of each element in the drawings are only for illustration, and are not used to limit the scope of the present disclosure.

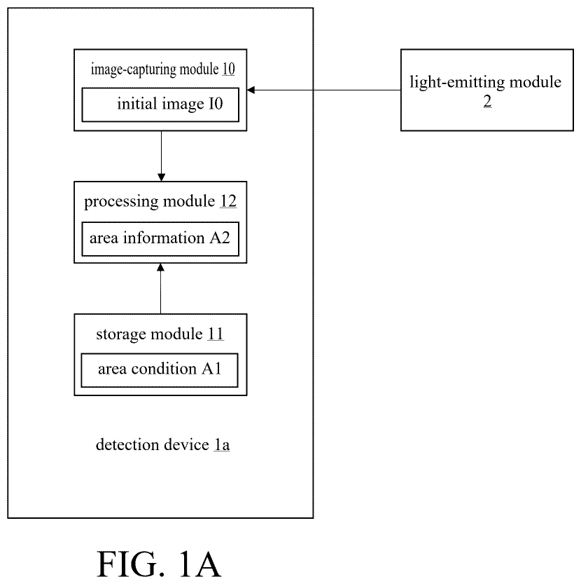

FIGS. 1A and 1B are respectively schematic diagrams showing the detection device and the electronic device according to some embodiments of the present disclosure. In the present disclosure, the detection device 1a is used to detect the light-emitting module 2. Specifically, the detection device 1a includes the image-capturing module 10, the storage module 11, and the processing module 12. Through detecting the light-emitting modules by the detection device 1a, the light-emitting modules that meet the standards and the light-emitting modules that do not meet the standards may be classified. Next, as shown in FIG. 1B, the light-emitting module 2 that meets the standards and the display panel 3 may be assembled to obtain the electronic device 4 that meets the standards. According to some embodiments, the light-emitting module 2 may be used to provide a light source for the display panel 3, and the display panel 3 may be a liquid crystal display panel. According to some embodiments, the light-emitting module 2 may be a device with a display function, and the light-emitting module 2 that meets the standards does not need to be assembled with a display panel.

As shown in FIG. 1A, the image-capturing module 10 is configured to capture the initial image I0 of the light-emitting module 2. In some embodiments, the image-capturing module 10 may include an optical lens and a photosensitive element coupled to the optical lens. For example, the optical lens may be or may include a telecentric lens, which allows the captured image to be unaffected by lens parallax within a certain physical distance while achieving a wide depth of field effect. Alternatively, the optical lens may also be a general lens, a wide-angle lens, a telephoto lens, a combination thereof, or other suitable lenses, but the present disclosure is not limited thereto. For example, the photosensitive element may be a charge-coupled device (CCD), a complementary metal-oxide-semiconductor (CMOS), a combination thereof, or other suitable photosensitive elements, but the present disclosure is not limited thereto.

As shown in FIG. 1A, the storage module 11 is configured to store the area condition A1. The initial image I0 of the light-emitting module 2 to be tested may be image processed by the processing module 12 to obtain the area information A2. The area information A2 may be compared with the area condition A1 to obtain a comparison result, which is used to determine whether the light-emitting module to be tested meets the area condition (compliance with the standards), and the detailed description thereof and various aspects will be further described hereinafter. In some embodiments, the storage module 11 may include volatile and/or nonvolatile memory. For example, the storage module 11 may include a random access memory (RAM), a read only memory (ROM), a hard disk drive, and/or other types of memory (e.g., a flash memory, a magnetic memory, and/or an optical memory), but the present disclosure is not limited thereto. The storage module 11 may include an internal memory (e.g., a RAM, a ROM, or a hard drive) and/or removable memory (e.g., through a universal serial bus to connect and removable). The storage module 11 may be a non-transitory computer-readable medium, but the present disclosure is not limited thereto.

As shown in FIG. 1A, the processing module 12 is configured to perform the following functions: receiving the initial image I0 of the light-emitting module 2 to be tested captured by the image-capturing module 10; performing image processing on the initial image I0 to obtain the area information A2; and comparing the area condition A1 with the area information A2 to determine whether the light-emitting module 2 belongs to the first group of light-emitting modules or the second group of light-emitting modules. In the present disclosure, the light-emitting modules 2 that meet the area condition A1 (compliance with the standards) may be defined into the first group of light-emitting modules, and the light-emitting modules 2 that do not meet the area condition A1 may be defined into the second group of light-emitting modules. In this way, in the subsequent process of assembling the light-emitting module 2 and the display panel 3, the light-emitting module 2 that meets the standard (that is, the light-emitting module 2 of the first group of light-emitting modules) may be selected to avoid using the light-emitting module 2 that does not meet the standard (that is, the light-emitting module 2 of the second group of light-emitting modules). Among them, the detailed description and various aspects of the area condition A1 and the area information A2 will be further described hereinafter.

In some embodiments, the processing module 12 may include a central processing unit, a graphics processing unit, a microprocessor, a controller, a microcontroller, a digital signal processor, a field-programmable gate array, an application-specific integrated circuit, and/or other types of processors, but the present disclosure is not limited thereto. In some embodiments, the processing module 12 may be implemented using hardware alone or a combination of hardware and software. In some embodiments, the processing module 12 may include one or more sub-processors, and the one or more sub-processors may be programmed to perform one or more operations described of the present disclosure (e.g., image processing described above), but the present disclosure is not limited thereto.

In some embodiments, the processing module 12 may also include memory. The examples of memory may be referred to above and the descriptions are omitted. A combination of processor and memory may be used to perform one or more operations (e.g., image processing). For example, a non-transitory computer-readable medium (e.g., a memory) may store a set of instructions (e.g., one or more instructions or code) for execution by a processor. The processor may execute a set of instructions to perform one or more operations described of the present disclosure. In some implementations, a set of instructions may be executed by one or more sub-processors, such that the one or more sub-processors perform one or more operations described of the present disclosure. In some implementations, a hardwired circuitry may be used in place of or in combination with instructions to perform one or more operations of the present disclosure. Therefore, implementations of the present disclosure are not limited to any specific combination of hardware circuitry and software.

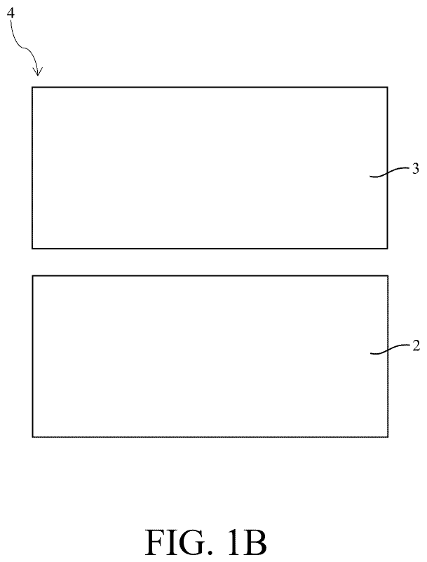

FIG. 2 is a schematic diagram showing the detection device according to other embodiments of the present disclosure. Compared with FIG. 1A, the detection device shown in FIG. 2 further includes the display device 13 and the control module 14.

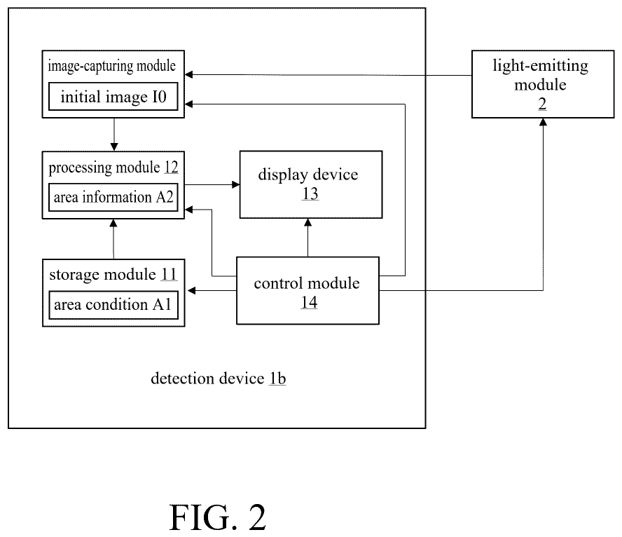

As shown in FIG. 2, the control module 14 is electrically connected to the light-emitting module 2, the image-capturing module 10, the storage module 11, the processing module 12, and the display device 13, and controls the operation of these modules or units to achieve the function of automatically detecting the light-emitting module 2. FIGS. 2 and 3 are schematic diagrams showing the operation of the detection device according to some embodiments of the present disclosure. The detection process is described hereinafter. First, in operation O1, the control module 14 controls the light-emitting module 2 to emit light. The light-emitting module 2 may include a plurality of light-emitting units arranged in a matrix. Next, in operation O2, the control module 14 controls the image-capturing module 10 to capture the light-emitting module 2 to obtain the initial image I0. In operation O3, the control module 14 controls the processing module 12 to receive the initial image I0. In operation O4, the control module 14 controls the processing module 12 to perform image processing on the initial image I0, so whether the light-emitting module 2 currently to be tested meets the standard is determined. According to some embodiments, whether the standard is met may indicate whether the area information A2 of the image of the light-emitting module 2 is consistent with the area condition A1. Specifically, the area information A2 meets the area condition A1, which means that the light-emitting module to be tested meets the standard. On the contrary, the area information A2 does not meet the area condition A1, which may mean that the light-emitting module to be tested does not meet the standard. The control module 14 may control the processing module 12 to transmit the comparison results to the display device 13. In operation O5, the control module 14 may control the display device 13 to display the comparison result. In operation O6, an operator may recheck the comparison results. In operation O7, when the operator confirms that the comparison result is correct, the status (that is, meets the standard or does not meet the standard) of the current light-emitting module 2 to be tested may be stored in the database for archiving for subsequent use in the process.

As shown in FIG. 3, in operations O5 and O6, the control module 14 may control the display device 13 to display the comparison result, so that the operator (or user) may see the comparison result by the display device 13. In some embodiments, specifically, after determining that the light-emitting module to be tested belongs to the second group of light-emitting modules that do not meet the standard, image processing performed by the processing module 12 may include visualization processing the light-emitting module to be tested so that the image may be displayed on the display screen for the user to view. For example, the control module 14 may cause the display device 13 to provide a display screen. The display screen may display the difference positions in the light-emitting module to be tested that do not meet the standards (do not meet the area condition), so that the operator may easily see the position that does not meet the standards by the display screen.

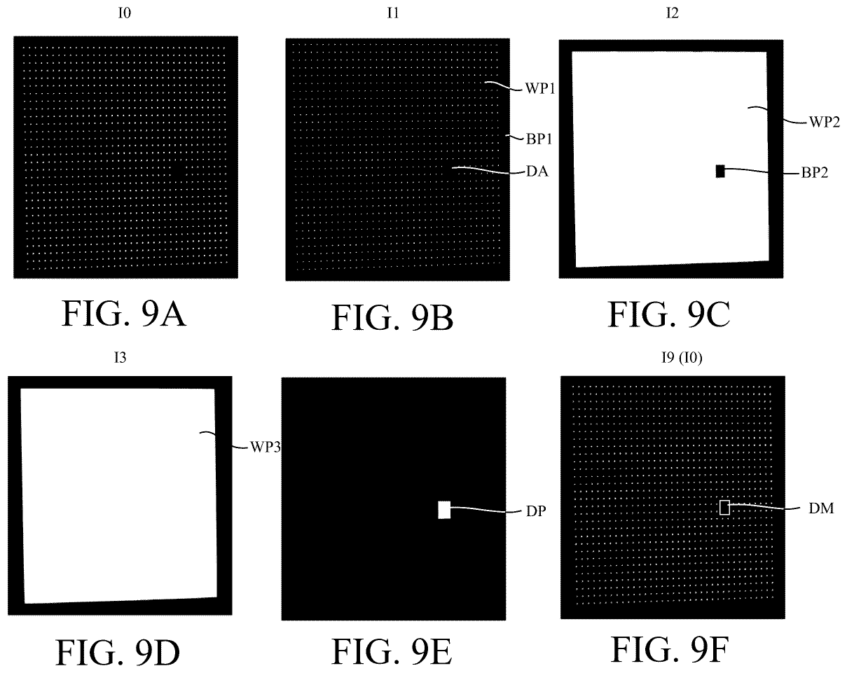

Taking the embodiment of FIG. 9F as an example, in FIG. 9F, the area condition A1 may be being less than or equal to a dark spot threshold. After detecting, in the case the light-emitting module to be tested does not meet the area condition A1, the control module 14 may cause the display device 13 to display the display screen 19. This display screen 19 may include the difference mark DM, which may display the position that does not meet the standard of the light-emitting module to be tested. That is, there are dark spots that do not meet the area condition A1 at this position. In this way, the operator may easily know the position where the light-emitting module to be tested does not meet the standard by seeing the difference mark DM by the display screen 19. This will be explained in detail in the following examples. The difference mark DM may be an arrow, an icon, a frame, etc., as long as it may show the position that does not meet the standards, and the present disclosure is not limited thereto. The difference mark DM in FIG. 9F is taken as an example of the frame line.

As shown in FIG. 2, in operation O7, when the operator confirms that the comparison result is correct, the current statue (that is, meets the standard or does not meet the standard) of the light-emitting module 2 may be stored in the database for being used in subsequent processes. Therefore, compared with the existing technology, the detection device of the present disclosure may operate automatically and effectively analyze the light-emitting module 2, thereby solving some problems caused by the large use of manpower.

According to some embodiments, as shown in FIG. 3, operations O1 to O5 may be automated operations performed by the control module 14 of the detection device 1b. In other words, the detection device 1b may automatically perform lighting up the light-emitting module 2 as described in operation O1, automatically perform activation of the image-capturing module 10 to capture the light-emitting module 2 as described in operation O2, and automatically perform image analysis and processing described in operations O3 to O5. According to some embodiments, the control module 14 may control at least one of the above operations to achieve automation. For example, the control module 14 may be configured to light up the light-emitting module 2 to be tested. The control module 14 may be configured to activate the image-capturing module 10 to capture the initial image I0 of the light-emitting module 2 to be tested. Therefore, compared with some existing detection devices that still require manual execution of the above steps, the detection device provided by the present disclosure may significantly reduce manpower requirements and reduce possible differences in manual operations.

According to some embodiments, as shown in FIG. 3, the control module 14 may sequentially execute the following steps according to a preset process. In operation O1, the light-emitting module 2 to be tested is lighted up. In operation O2, the image-capturing module 10 is activated to capture the initial image of the light-emitting module 2 to be tested. In operation O3, the initial image is received. In operation O4, image processing on the initial image is performed to obtain the area information A2, and the area condition is compared with the area information to determine whether the light-emitting module to be tested belongs to the first group of light-emitting modules or the second group of light-emitting modules. The control module 14 may further perform operation O5. Among them, the control module 14 may be configured to receive the comparison result and transmit the comparison result to the display device 13, and then may control the display device 13 to display the comparison result.

In some embodiments, the display device 13 may be or may include a liquid crystal display, an organic light-emitting diode (OLED) display, an inorganic light-emitting diode display, a mini LED, a micro LED display, a quantum dot LED (QLED/QDLED) display, a combination thereof, or other suitable displays, but the present disclosure is not limited thereto.

According to some embodiments, although the control module 14 shown in the detection device 1b of FIG. 2 is not shown in the detection device 1a of FIG. 1, but the present disclosure may still implement the functions of the control module 14 in other ways. For example, operations O1 to O5 may be automatically performed through a combination of the processing module 12 and the storage module 11. Therefore, the detection device 1a, the detection device 1b, or other similar implementations of the present disclosure may perform automated detection functions and are not limited to the above description.

In some embodiments, the control module 14 may include a processor. The examples of processors may be referred to above and the descriptions are omitted. In some embodiments, the control module 14 may also include memory. The examples of memory may be referred to above and the descriptions are omitted. A combination of processor and memory may be used to perform one or more operations (e.g., the control functions described above). It should be noted that the configuration of the detection device 1b shown in FIG. 2 is only an example, and the present disclosure is not limited thereto. In some embodiments, the control module 14 may be shared with processing module 12. In other words, the control module 14 may be replaced with the processing module 12 and the control module 14 may be omitted. In other embodiments, the control module 14 may be part of processing module 12.

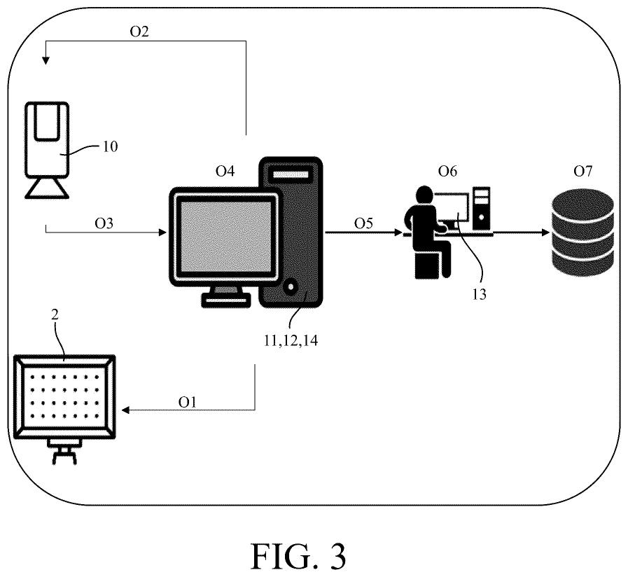

In the above, the detection device for detecting the light-emitting module has been described in detail. Next, the manufacturing method of the electronic device 4 will be provided. In some embodiments, the above-mentioned detection device may be used to perform the detection process in the manufacturing method of the electronic device 4, but the present disclosure is not limited thereto. FIG. 4 is a flowchart showing the manufacturing method of the electronic device according to some embodiments of the present disclosure.

As shown in FIG. 4, in step S11, the area condition A1 is stored. The area condition A1 (A12) may be being greater than or equal to an area threshold. Alternatively, the area condition A1 may be being less than or equal to an area threshold. The area threshold may be an area value or may be an area ratio. Taking the embodiment of FIG. 9F as an example, in FIG. 9F, the area condition A12 may be a dark spot condition, for example, being less than or equal to a dark spot threshold. For example, the dark spot threshold may be 10 mm² and the area condition A12 may be being less than or equal to 10 mm². After the image processing is performed to obtain the area information A22, the area information A22 may be compared with the area condition A1 (A12). The area information A22 meets the area condition A1, which means that the light-emitting module to be tested meets the standard, that is, it meets the dark spot standard. On the contrary, the area information A22 does not meet the area condition A1, which may mean that the light-emitting module to be tested does not meet the standard, that is, it does not meet the dark spot standard.

In a similar manner, the area conditions A1 may be stored in step S11, according to actual needs. The area conditions A1 may include the first area condition A11, the second area condition A12, the third area condition A13, and the fourth area condition A14. According to the different area conditions A1, the different area information A2 may be obtained after image processing. The area information A2 may include the first area information A21, the second area information A22, the third area information A23, and the fourth area information A24. The first area information A21 may be compared with the first area condition A11, the second area information A22 may be compared with the second area condition A12, the third area information A23 may be compared with the third area condition A13, and the fourth area information A24 may be compared with the fourth area condition A14. For example, the first area condition A11 may be a bright area ratio condition, the second area condition A12 may be a dark spot condition, the third area condition A13 may be a brightness standard deviation condition, and the fourth area condition A14 may be a bright spot condition. Several examples will be described in detail hereinafter.

In step S12, a plurality of light-emitting modules 2 are provided. For example, the light-emitting modules 2 may be light-emitting modules that are produced in the same batch or they may be light-emitting modules that are produced in different batches, but the present disclosure is not limited thereto. In some embodiments, the light-emitting modules 2 may be identical to each other, but the present disclosure is not limited thereto. In the present disclosure, each light-emitting module 2 includes light-emitting elements, and these light-emitting elements may be arranged in a matrix on the substrate of the light-emitting module 2. For example, the light-emitting elements may be arranged in triangles, rectangles, polygons, circles, ovals, special shapes, combinations thereof, or other suitable shapes, but the present disclosure is not limited thereto.

In step S13, the detection process is performed on each light-emitting module 2 (hereinafter also referred to as the light-emitting module 2 to be tested) to determine whether the light-emitting module 2 belong to the first group of light-emitting modules that meets the area condition A1 or the second group of light-emitting modules that do not meet the area condition A1. In some embodiments, the detection process may be performed on the light-emitting modules 2 in sequence, but the present disclosure is not limited thereto. In other embodiments, the detection process may be performed on two or more light-emitting modules 2 at the same time to shorten the time of this step.

Specifically, the detection process includes sub-steps S130 to S133. In sub-step S130, the light-emitting module 2 to be tested is lighted up. In sub-step S131, the initial image I0 of the light-emitting module 2 to be tested is captured. For example, one (or more) light-emitting module 2 may be placed in the capturing area of the image-capturing module 10 as shown in FIG. 1A, and the initial image I0 of the current light-emitting module 2 may be obtained through the image-capturing module 10. In sub-step S132, image processing is performed on the initial image I0 to obtain the area information A2. For example, image processing may be performed on the initial image I0 by the processing module 12 as shown in FIG. 1A. In some embodiments, the image processing may include any one or combination of the four image processing described hereinafter, but the present disclosure is not limited thereto. In sub-steps S133, the area condition A1 and the area information A2 are compared to determine whether the light-emitting module 2 to be tested belongs to the first group of light-emitting modules or the second group of light-emitting modules.

Although the present disclosure provides four area conditions A1, these conditions may be used individually or arbitrarily as judgment criteria according to product requirements, and are not limited to the above four area conditions A1 that must be adopted at the same time. For example, one of the above four area conditions A1 may be arbitrarily adopted, and whether the light-emitting module 2 to be tested meets the standard is determined based on whether the corresponding area information A2 meets the area condition A1. In some embodiments, when the four area information A21, A22, A23, and A24 completely meet the four area conditions A11, A12, A13, and A14 respectively, it is determined that the current light-emitting module 2 to be tested belongs to the first group of light-emitting modules that meets the standards. That is, the light-emitting module 2 to be tested is a good product. On the contrary, when the area information A2 partially meets or does not meet all four area conditions A1 (e.g., meets one to three or none of them), it is determined that the current light-emitting module 2 to be tested belongs to the second group of light-emitting modules that do not meet the standards. That is, the light-emitting module 2 to be tested is a defective product.

In order to make sub-steps S132 and S133 more clear and understandable, four embodiments are provided hereinafter to describe possible operations of image processing (e.g., how to obtain area information A2 through image processing) and possible pre-operations of image processing (e.g., how to store the area condition A1).

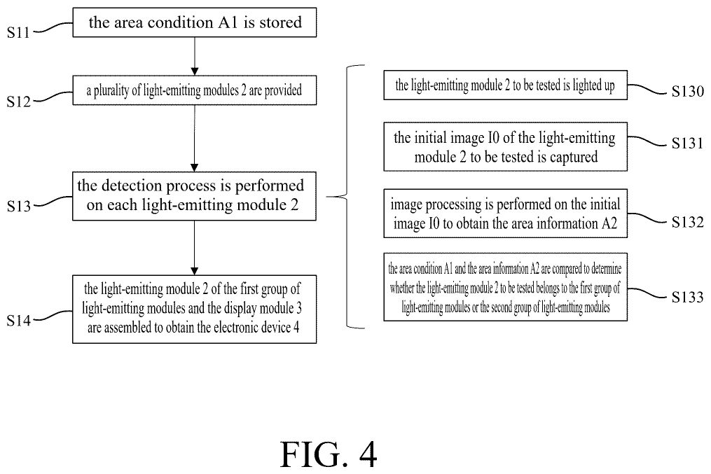

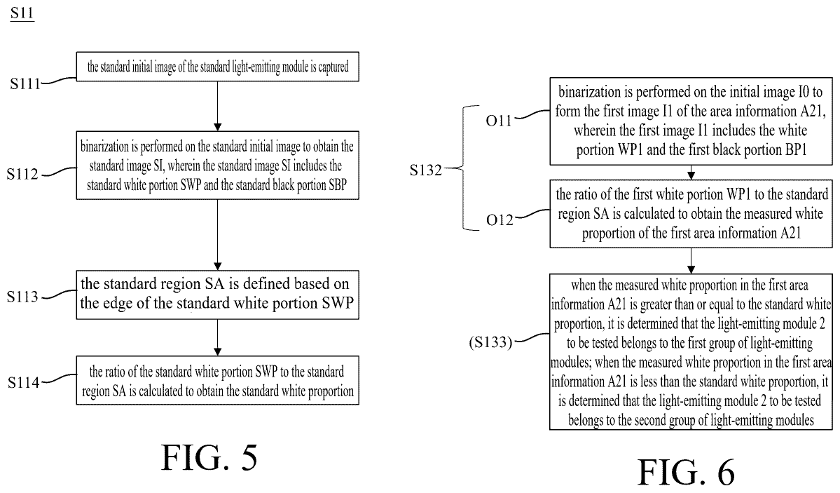

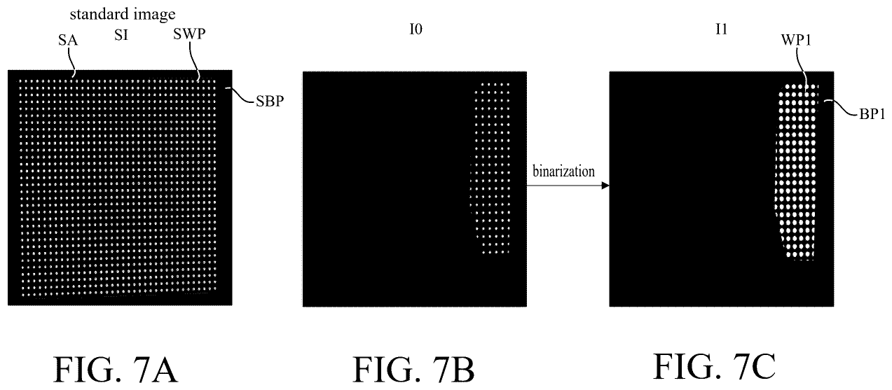

FIGS. 5, 6 and 7A to 7C correspond to the first image processing and its pre-operations. It mainly detects whether the light-emitting module meets the bright area ratio standard. Among them, FIG. 5 is a flowchart showing the pre-operations of the image processing according to some embodiments of the present disclosure. FIG. 6 is a flowchart showing the image-processing operation according to some embodiments of the present disclosure. FIGS. 7A to 7C are schematic diagrams showing the different stages of the image processing according to some embodiments of the present disclosure. In the following embodiments, the first image processing may be used to detect picture abnormalities, but the present disclosure is not limited thereto. In this embodiment, the area condition A1 may include the first area condition A11, and the area information A2 may include the first area information A21. The first area condition A11 may include being greater than or equal to a standard white proportion, and the first area information A21 may include a measured white proportion. By comparing the measured area information with the set area conditions, whether the light-emitting module to be tested meets or does not meet the area condition may be known, so that whether the light-emitting module to be tested meets the bright area ratio standard may be known.

As shown in FIGS. 5 and 7A, in the pre-operations of the first image processing, the step of storing the area condition A1 (A11) (that is, step S11 in FIG. 4) may include sub-steps S111 to S114. In sub-step S111, the standard initial image of the standard light-emitting module is captured. In the present disclosure, the term “standard light-emitting module” is a light-emitting module that meets the standard after being tested and may have no defects or defects within the allowable value. The aforementioned detection may be the detection method mentioned of the present disclosure or other detection methods. In sub-step S112, binarization is performed on the standard initial image to obtain the standard image SI (e.g., FIG. 7A). Among them, the standard image SI includes the standard white portion SWP and the standard black portion SBP. Specifically, “binarization” is used to transform the standard initial image into the standard image SI composed of pure black pixels (the grayscale value is 0) and pure white pixels (the grayscale value is 255) to eliminate noise possibly existed of the image. In some cases, the binarization conditions (that is, the grayscale value as the classification boundary) may be adjusted according to the actual situation. For example, when the white spot of the light-emitting element in the standard initial image includes the light-emitting element body (high brightness) and the halo around the light-emitting element body (low brightness), the binarization conditions may be adjusted (e.g., using a higher grayscale value as the boundary) until the white spot of the light-emitting element in the converted standard image SI shows the body of the light-emitting element and does not show halo. In other words, the standard white portion SWP corresponds to the light-emitting elements of the standard light-emitting module, while the standard black portion SBP corresponds to the non-light-emitting elements of the standard light-emitting module (e.g., the substrate, the circuit, and protective layer, etc.). The initial image shows grayscale. The binarized image only has pure black pixels (the grayscale value is 0) and pure white pixels (the grayscale value is 255), and has no grayscale.

It should be noted that the light emitted by the light-emitting module of the present disclosure may include white, blue, red, green, other suitable colors, or a combination thereof. Therefore, the original image with color may be converted into an image composed of black and white through binarization processing. Alternatively, in some embodiments, the initial image may also be an image composed of black and white.

In sub-step S113, the standard region SA is defined based on the edge of the standard white portion SWP. That is, the specific area is defined based on the arrangement range of the light-emitting elements, and this specific area is used to calculate whether the number of light-emitting elements meets expectations. Herein, it may be assumed that the size of each standard white portion SWP (or the measured white portion WP1 hereinafter) representing the light-emitting element is similar or the same. Therefore, the number of light-emitting elements may be estimated by calculating the ratio between the unit area (e.g., the standard region SA) and the total areas of the standard white portion SWP (or the white portion WP1 measured hereinafter). In sub-step S114, the ratio of the standard white portion SWP to the standard region SA is calculated to obtain the standard white proportion (the standard white portion SWP/the standard region SA=the standard white proportion). That is, the proportion occupied by the light-emitting elements in the unit area (e.g., the area of a single light-emitting module) may be obtained. Through the above method, the standard region SA and the standard white proportion may be obtained. In this way, the first area condition A11 may be defined as being greater than or equal to the standard white proportion. This first area condition A11 may be used to detect whether the light-emitting module meets the bright area ratio standard. According to some embodiments, the standard white proportion may be between 65% and 95%, for example, between 75% and 95% or between 75% and 90%. For example, the first area condition A11 may be being greater than or equal to 75%. Next, as shown in FIGS. 6, 7B, and 7C, in sub-step S132, the first type of image processing may include operations O11 to O12. In operation O11, binarization is performed on the initial image I0 (e.g., FIG. 7B) to form the first image I1 (e.g., FIG. 7C) of the area information A2, wherein the first image I1 includes the white portion WP1 and the first black portion BP1. Similar to the above-mentioned binarization operation, operation O11 may eliminate noise or halo of the light-emitting element of the initial image I0 to form the clear first image I1 composed of black pixels and white pixels. It should be noted that the white pixels in FIG. 7C are more obvious than those in FIG. 7B because the binarization threshold may be adjusted so that the white halo that is not obvious in the human eye is also included of the first white portion WP1. However, the present disclosure is not limited to adjusting the binarization threshold to make white pixels larger. In other embodiments, the binarization threshold may also be adjusted to maintain the size or reduce the size, which may be adjusted according to actual needs.

In operation O12, the ratio of the first white portion WP1 to the standard region SA is calculated to obtain the measured white proportion of the first area information A21 (the measured white portion WP1/the standard region SA=the measured white proportion). After operation O12, in sub-step S133, when the measured white proportion of the first area information A21 meets the first area condition A11, that is, being greater than or equal to the standard white proportion, it is determined that the light-emitting module 2 to be tested belongs to the first group of light-emitting modules. When the measured white proportion in the first area information A21 does not meet the first area condition A11, that is, being smaller than the standard white proportion, it is determined that the light-emitting module 2 to be tested belongs to the second group of light-emitting modules. For example, the measured white proportion of the light-emitting module 2 to be tested in FIG. 7C is significantly smaller than the standard white proportion of the standard light-emitting module in FIG. 7A. In other words, the current light-emitting module 2 to be tested does not meet the first area condition A11 and is a defective product with abnormal images.

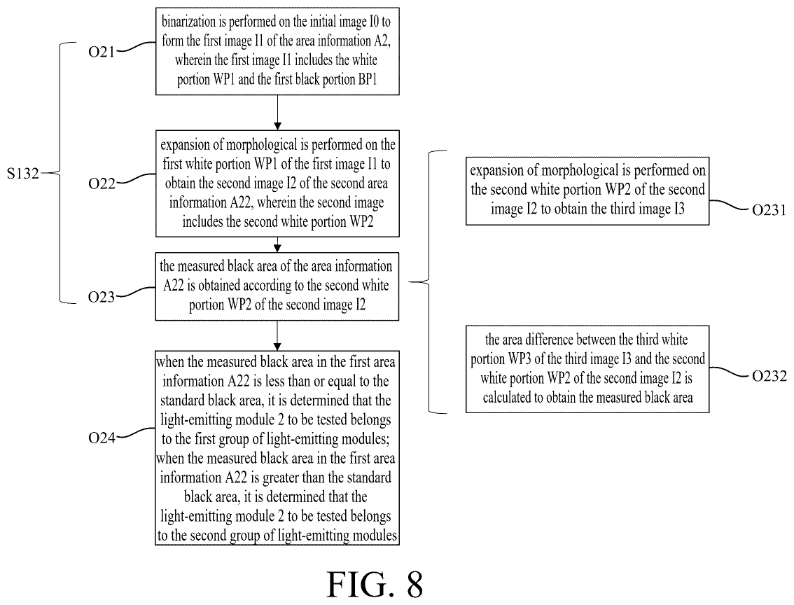

FIGS. 8 and 9A to 9F correspond to the second image-processing operation. It mainly detects whether the light-emitting module meets the dark spot standard. Among them, FIG. 8 is a flowchart showing the operations of the image processing according to other embodiments of the present disclosure. FIGS. 9A to 9F are schematic diagrams showing the different stages of the image processing according to other embodiments of the present disclosure. In the following embodiments, the second image processing may be used to detect dark spots, but the present disclosure is not limited thereto. In this embodiment, the area condition A1 may include the second area condition A12, and the area information A2 may include the second area information A22. The second area condition A12 may include being less than or equal to a standard black area, and the second area information A22 may include a measured black area. By comparing the measured area information with the set area conditions, whether the light-emitting module to be tested meets or does not meet the area condition is known, so that whether the light-emitting module to be tested meets the dark spot standard is known.

As shown in FIGS. 8, 9A, and 9F, in sub-step S132, the second image processing may include operations O21 to O23. In operation O21, binarization is performed on the initial image I0 (e.g., FIG. 9A) to form the first image I1 (e.g., FIG. 9B) of the area information A2, wherein the first image I1 includes the white portion WP1 and the first black portion BP1. Similar to the above-mentioned binarization operation, operation O21 may eliminate noise or halo of the light-emitting element of the initial image I0 to form the clear first image I1 composed of black pixels and white pixels.

In operation O22, expansion of morphological is performed on the first white portion WP1 of the first image I1 to obtain the second image I2 of the second area information A22, wherein the second image includes the second white portion WP2 and includes the second black portion BP2 possibly existed. Specifically, “expansion” refers to expanding the first white portions WP1 that are separated from each other of the first image I1 through structuring elements to fill or cover the gap between two adjacent first white portions WP1 (that is, the first black portion BP1). In some cases, the conditions of the structural elements (i.e., the degree to which the first white portion WP1 fills or covers the first black portion BP1) may be adjusted according to actual conditions. For example, when a defect occurs in the first white portion WP1 arranged in a matrix (e.g., the dark area DA without periodically arranged white dots shown in FIG. 9B), the dot-like (or circular) first white portion WP1 expands into the second white portion WP2 until the second white portion WP2 surrounds the second black portion BP2 in the dark area DA (e.g., FIG. 9C).

In operation O23, the measured black area of the area information A2 is obtained according to the second white portion WP2 of the second image I2. For example, the area of the second black portion BP2 surrounded by the second white portion WP2 may be directly measured to obtain the measured black area.

However, the present disclosure is not limited thereto. In other embodiments, operation O23 may also include sub-operations O231 and O232, which are used to replace the above-mentioned measurement method. For example, in sub-operation O231, expansion of morphological is performed on the second white portion WP2 of the second image I2 (e.g., FIG. 9C) to obtain the third image I3 (e.g., FIG. 9D), wherein the third image I3 includes the third white portion WP3 and does not include the black portion. In other words, the third image I3 may substantially composed of the third white portion WP3. Next, in sub-operation O232, the area difference between the third white portion WP3 of the third image I3 and the second white portion WP2 of the second image I2 is calculated to obtain the measured black area. For example, the second white portion WP2 of FIG. 9C may be subtracted from the third white portion WP3 of FIG. 9D to produce the difference portion DP as shown in FIG. 9E (the third white portion WP3−the second white portion WP2=the difference portion DP). In this way, the area of the difference portion DP may be measured to obtain the measured black area, so that the position of the difference portion DP may be obtained.

After operation O23, in sub-step S133, when the measured black area of the second area information A22 meets the second area condition A12, that is, when the measured black area of the area information A22 is less than or equal to the standard black area, it is determined that the light-emitting module 2 to be tested belongs to the first group of light-emitting modules. When the measured black area of the area information A22 does not meet the area condition A1, that is, larger than the standard black area, it is determined that the light-emitting module 2 to be tested belongs to the second group of light-emitting modules. For example, the standard black area (the area threshold) may be defined as a specific value, such as a specific value in units of mm² and cm². When the measured black area exceeds this specific value, the current light-emitting module 2 to be tested is determined to be a defective product with dark spots. According to some embodiments, the standard black area threshold may be in the range of 1 to 15 mm², for example, in the range of 3 to 12 mm² or 7 to 11 mm², but the present disclosure is not limited thereto. For example, the standard black area threshold (the dark spot threshold) may be 10 mm². For example, the second area condition A12 may include being less than or equal to the standard black area. The standard black area threshold may be adjusted according to the needs of the light-emitting module. In some embodiments, after operation O23 or after sub-step S133, visualization processing may also be performed on the initial image I0 or the first image I1 so that the image may be displayed in the display screen for the user to view. For example, the difference mark DM may be marked in the initial image I0 of FIG. 9A according to the difference portion DP shown in FIG. 9E to form the display screen 19 as shown in FIG. 9F. The control module 14 may cause the display device 13 to display the display screen 19. The display screen 19 may include the difference mark DM, which may display the position where the light-emitting module to be tested does not meet the standard, that is, this position has a dark spot that does not meet the dark spot standard (the area condition A1). For example, the difference mark DM may be a frame line or a mark. In this way, the operator may quickly find the location of the problem point through the frame line in the display screen 19 as shown in FIG. 9F.

It should be noted that the second image processing embodiment takes the defective light-emitting module 2 as an example. For the light-emitting module 2 without defects, after the operation O22 is performed, the entire second image I2 no longer includes the black portion. In other words, the measured black area is substantially 0. Therefore, sub-operation O231 and sub-operation O232 may be omitted.

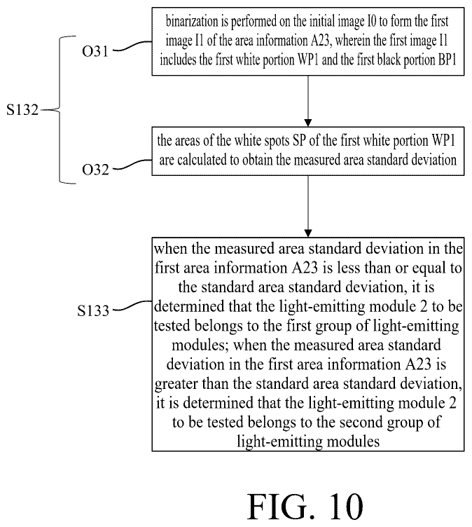

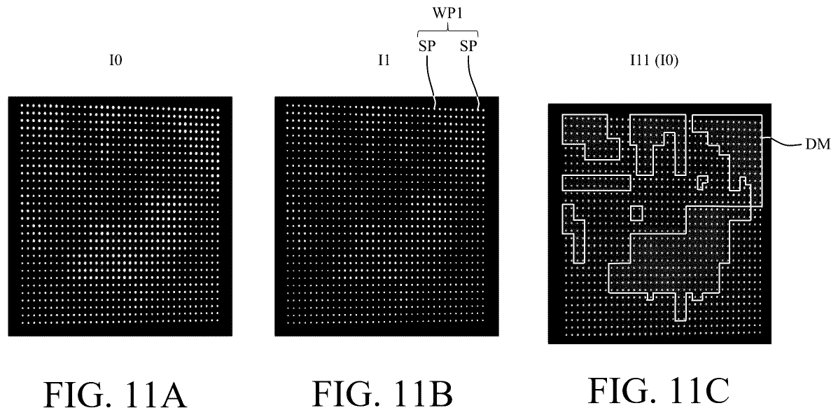

FIGS. 10 and 11A to 11C correspond to the third image-processing operation. It is mainly used to detect whether the light-emitting module meets the standard of brightness standard deviation, that is, it is used to detect whether there is uneven brightness or darkness. Among them, FIG. 10 is the flowchart showing the operations of the image processing according to some embodiments of the present disclosure. FIGS. 11A to 11C are schematic diagrams showing the different stages of the image processing according to further embodiments of the present disclosure. In this embodiment, the area condition A1 may include the third area condition A13, and the area information A2 may include the third area information A23. The third area condition A13 may include being less than or equal to an area standard deviation threshold, and the third area information A23 may include a measured area standard deviation. By comparing the measured area information with the set area conditions, whether the light-emitting module to be tested meets or does not meet the area condition is known, so that whether the light-emitting module to be tested has uneven brightness or darkness is known.

As shown in FIGS. 10, 11A, and 11B, in sub-step S132, the third image processing may include operations O31 to O32. In operation O31, binarization is performed on the initial image I0 (e.g., FIG. 11A) to form the first image I1 (e.g., FIG. 11B) of the area information A2, wherein the first image I1 includes the first white portion WP1 and the first black portion BP1. Different from the above-mentioned binarization operation, operation O31 eliminates the noise in the initial image I0 and retains the halo of the light-emitting element. Specifically, when the brightness of the light emitted by the light-emitting element is higher, the halo in the initial image I0 or the first image I1 is more obvious. That is, the area of the white spots SP (i.e., each light-emitting element and its halo) of the first white portion WP1 is larger. Therefore, the binarization condition in operation O31 (that is, the grayscale value as the classification boundary) may be made lower than in the above embodiment (e.g., a lower grayscale value is used as the boundary), so that the white spots SP of the light-emitting elements in the converted first image I1 still includes the halo of the light-emitting elements.

In operation O32, the areas of the white spots SP of the first white portion WP1 are calculated to obtain the measured area standard deviation. By measuring the area standard deviation, the degree of dispersion of the brightness of the light-emitting module 2 to be tested may be determined. When the measured area standard deviation is larger, it means that the brightness of the current light-emitting module 2 to be tested is more uneven. After operation O32, in sub-step S133, when the measured area standard deviation of the third area information A23 meets the third area condition A13, that is, being less than or equal to the area standard deviation threshold, it is determined that the light-emitting module 2 to be tested belongs to the first group of light-emitting modules. When the measured area standard deviation of the third area information A23 does not meet the third area condition A13, that is, being greater than the area standard deviation threshold, it is determined that the light-emitting module 2 to be tested belongs to the second group of light-emitting modules. For example, the standard area standard deviation may be defined as 10, and the measured area standard deviation in FIG. 11B is 53, which indicates that the current light-emitting module 2 to be tested is a defective product with uneven light and dark. According to some embodiments, the area standard deviation threshold may be between 3 and 80, for example, 5 to 70 or 8 to 65, but the present disclosure is not limited thereto. For example, the third area condition A13 may include being less than or equal to the area standard deviation threshold.

In some embodiments, after operation O32 or sub-step S133, visualization processing may also be performed on the initial image I0 or the first image I1, so that the image may be displayed in the display screen for the user to view. For example, the average area of all white spots SP may be calculated first. Next, in the initial image I0 in FIG. 11A or the first image I1 in FIG. 11B, the white spot SP with an area larger than the average area is marked with the difference mark DM to form the display screen I11 as shown in FIG. 11C. The control module 14 may cause the display device 13 to display this display screen I11. This display screen I11 may include the difference mark DM, which may display the position where the light-emitting module to be tested does not meet the standard, that is, the position does not meet the area standard deviation (the area condition A1). For example, in FIG. 11C, a particularly bright white spot SP is shown as a red point, or a particularly bright white spot SP is marked with a frame. For example, in FIG. 11C, the portion framed by the frame line DM may be a portion that is greater than the area standard deviation threshold, that is, a portion with poor light and dark uniformity. In this way, the operator may quickly find the position of the problem point through the frame line in FIG. 11C.

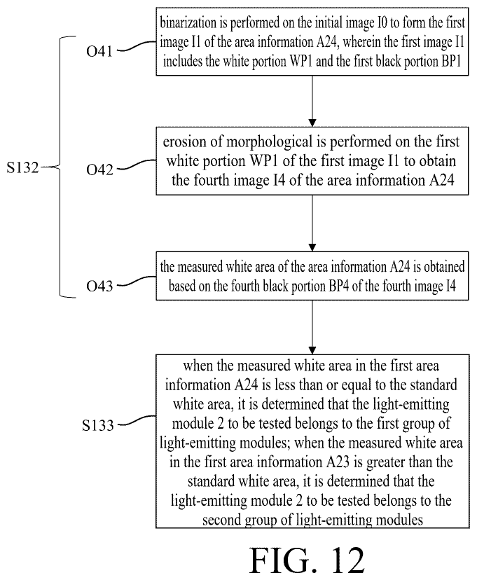

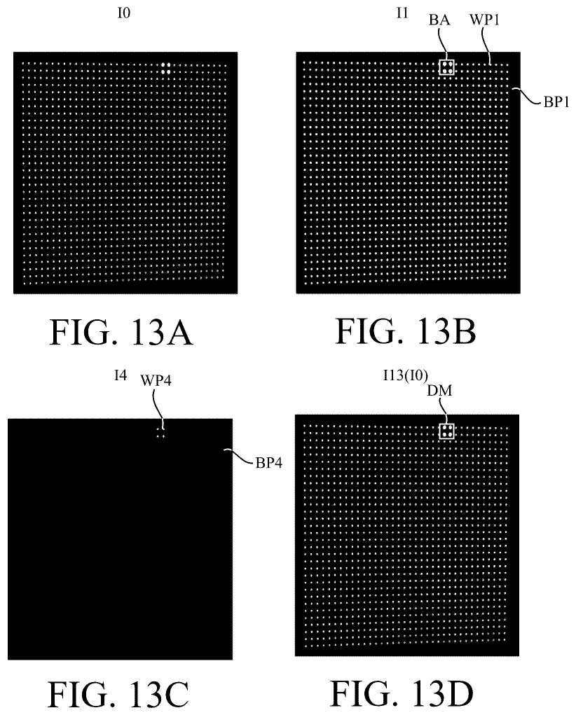

FIGS. 12 and 13A to 13C correspond to the fourth image-processing operation. It mainly detects whether the light-emitting module meets the standards of bright spots. Among them, FIG. 12 is a flowchart showing the operations of the image processing according to some embodiments of the present disclosure. FIGS. 13A to 13C are schematic diagrams showing the different stages of the image processing according to further embodiments of the present disclosure. In this embodiment, the area condition A1 may include the fourth area condition A14, and the area information A2 may include the fourth area information A24. The fourth area condition A14 may include being less than or equal to a standard white area, and the fourth area information A24 may include a measured white area. By comparing the measured area information with the set area conditions, whether the light-emitting module to be tested meets or does not meet the area condition is known, so that whether the light-emitting module to be tested meets the bright spot standard is known.

As shown in FIGS. 12 and 13A to 13C, in sub-step S132, the second image processing may include operations O41 to O43. In operation O41, binarization is performed on the initial image I0 (e.g., FIG. 13A) to form the first image I1 (e.g., FIG. 13B) of the area information A2, wherein the first image I1 includes the white portion WP1 and the first black portion BP1. Similar to the binarization operation of the third image processing, operation O41 eliminates the noise of the initial image I0 and retains the halo of the light-emitting element.

In operation O42, erosion of morphological is performed on the first white portion WP1 of the first image I1 (e.g., FIG. 13B) to obtain the fourth image I4 of the area information A2 (e.g., FIG. 13C), wherein the fourth image I4 includes the fourth black portion BP4 and includes the fourth white portion WP4 possibly existed. Specifically, “erosion” refers to using structural elements to shrink the first white portion WP1 of the first image I1 until it is filled or covered by the first black portion BP1. In some cases, the conditions of the structural elements (i.e., the degree to which the first black portion BP1 fills or covers the first white portion WP1) may be adjusted according to actual conditions. For example, when defects occur of the first white portion WP1 arranged in a matrix (e.g., the bright area BA with particularly large white dots in FIG. 13B), the dot-shaped (or circular) first white portion WP1 shrinks until the fourth black portion BP4 surrounds the fourth white portion WP4 in the bright area BA (e.g., FIG. 13C).

In operation O43, the measured white area of the area information A2 is obtained based on the fourth black portion BP4 of the fourth image I4. At this time, the area of the fourth white portion WP4 surrounded by the fourth black portion BP4 may be directly measured to obtain the measured white area.

After operation O43, in sub-step S133, when the measured white area of the area information A2 meets the area condition A1, that is, being less than or equal to the standard white area, it is determined that the light-emitting module 2 to be tested belongs to the first group of light-emitting modules. When the measured white area of the area information A2 does not meet the area condition A1, that is, being larger than the standard white area, it is determined that the light-emitting module 2 to be tested belongs to the second group of light-emitting modules. For example, the standard white area (the area threshold) may be defined as a specific value, such as a specific value in units of mm² and cm². When the measured white area exceeds this specific value, the current light-emitting module 2 to be tested is determined to be a defective product with bright spots. According to some embodiments, the standard white area threshold may be in the range of 0.05 to 1.5 mm², for example, in the range of 0.08 to 1 mm², in the range of 0.09 to 0.3 mm², or in the range of 0.09 to 0.2 mm², but the present disclosure is not limited thereto. The standard white area threshold may be adjusted according to the needs of the light-emitting module.

In some embodiments, after operation O43 or sub-step S133, visualization processing may also be performed on the initial image I0 or the first image I1, so that the image may be displayed in the display screen for the user to view. For example, the difference mark DM may be marked in the initial image I0 of FIG. 13A or the first image I1 of FIG. 13B according to the bright area BA shown in FIG. 13C, to form the display screen 113 as shown in FIG. 13D. The control module 14 may cause the display device 13 to display the display screen 113. The display screen I 13 may include the difference mark DM, which may display the position where the light-emitting module to be tested does not meet the standard, that is, this position has a bright spot that does not meet the bright spot standard (the area condition A1). For example, the difference mark DM may be a frame line or a mark. In this way, the operator may quickly find the position of the problem point through the frame line.

It should be noted that the fourth image processing embodiment takes the defective light-emitting module 2 to be tested as an example. For the light-emitting module 2 to be tested without defects, after the operation O42 is performed, the entire fourth image 14 no longer includes the white portion. In other words, the measured white area is substantially 0.

According to some embodiments, FIG. 3, the storage module 11, the processing module 12, and the control module 14 may be integrated into a host, and the host may be electrically connected to the display device 13 to display the comparison results obtained by the host onto the display device 13. Before performing the detection, the user may input the required area condition A1 into the storage module 11 of the host as needed. For example, the user may input different parameters (or detection thresholds) into the storage module 11 according to the detection items. For example, in the above-mentioned first specific embodiment, for detecting whether the bright area ratio is met, a threshold value of the standard white proportion may be input, and the first area condition A11 including being greater than or equal to the standard white proportion may be obtained. In the above second specific embodiment, for detecting whether the dark spot standard is met, a threshold value of the standard black area may be input, and the second area condition A12 including being less than or equal to the standard black area may be obtained. In the above third specific embodiment, for detecting whether the brightness uniformity is met, an area standard deviation threshold may be input, and the third area condition A13 including being less than or equal to the area standard deviation threshold may be obtained. In the above fourth specific embodiment, for detecting whether the bright point standard is met, a threshold value of the standard white area may be input, and the fourth area condition A14 including being less than or equal to the standard white area may be obtained.

As shown in FIGS. 1B and 4, in step S14, the light-emitting module 2 of the first group of light-emitting modules and the display module 3 are assembled to obtain the electronic device 4. Since the detection process in step S13 has classified the defective light-emitting modules into the second group of light-emitting modules, step S14 may effectively avoid assembling substandard electronic devices 4.

In some embodiments, as shown in FIG. 1B, the display module 3 may be or may include a liquid crystal display, an organic light-emitting diode (OLED) display, an inorganic light-emitting diode display, or a mini LED, a micro LED display, a quantum dot LED (QLED/QDLED) display, a combination thereof, or other suitable displays, but the present disclosure is not limited thereto.

In summary, the present disclosure provides a manufacturing method and a detection device for an electronic device. Among them, the manufacturing method of the electronic device captures an image of the light-emitting module, performs image processing on the image, and compares the area information of the image with the area condition. By using the compliance with the area conditions as the testing standard for eligibility, the problems caused by manual detection are effectively solved. In addition, the detection device integrates multiple modules and units to automatically perform the detection process of the light-emitting module, thereby effectively increasing the speed of detection and effectively solving problems caused by manual inspection.

In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A manufacturing method of an electronic device, comprising:
storing an area condition;
providing a plurality of light-emitting modules;
performing a detection process on each of the plurality of light-emitting modules, wherein the detection process performed on each of the plurality of light-emitting modules comprises:
lighting up a light-emitting module to be tested;
capturing an initial image of the light-emitting module to be tested;
performing image processing on the initial image to obtain area information; and
comparing the area condition with the area information of the light-emitting module to be tested to determine whether the light-emitting module to be tested belongs to a first group of light-emitting modules or a second group of light-emitting modules, wherein the light-emitting module to be tested with the area information meeting the area condition belongs to the first group of light-emitting modules, and the light-emitting module to be tested with area information that does not meet the area condition belongs to the second group of light-emitting modules; and
assembling a light-emitting module of the first group of light-emitting modules and a display panel to obtain the electronic device.

2. The manufacturing method of the electronic device as claimed in claim 1,
wherein performing the image processing comprises:
performing binarization on the initial image to obtain a first image of the area information, wherein the first image comprises a first white portion and a first black portion.

3. The manufacturing method of the electronic device as claimed in claim 2, wherein the area condition comprises being greater than or equal to a standard white proportion, and the area information comprises a measured white proportion.

4. The manufacturing method of the electronic device as claimed in claim 3, wherein storing the area condition comprises obtaining a standard region and the standard white proportion, wherein
performing the image processing further comprises:
calculating a proportion of the first white portion to the standard region to obtain the measured white proportion of the area information; and
comparing the area condition with the area information of the light-emitting module to be tested comprises:
when the measured white proportion of the area information is greater than or equal to the standard white proportion, the light-emitting module to be tested is determined to belong to the first group of light-emitting modules; when the measured white proportion of the area information is less than the standard white proportion, the light-emitting module to be tested is determined to belong to the second group of light-emitting modules.

5. The manufacturing method of the electronic device as claimed in claim 4,
wherein storing the area condition comprises:
capturing a standard initial image of a standard light-emitting module;
performing binarization on the standard initial image to obtain a standard image, wherein the standard image comprises a standard white portion and a standard black portion;
defining the standard region based on edges of the standard white portion; and
calculating a proportion of the standard white portion to the standard region to obtain the standard white proportion.

6. The manufacturing method of the electronic device as claimed in claim 2,
wherein the area condition comprises being less than or equal to a standard black area, and the area information comprises a measured black area.

7. The manufacturing method of the electronic device as claimed in claim 6, wherein
performing the image processing further comprises:
performing dilation on the first white portion of the first image to obtain a second image of the area information, wherein the second image comprises a second white portion; and
obtaining the measured black area of the area information based on the second white portion of the second image;
comparing the area condition with the area information of the light-emitting module to be tested comprises:
when the measured black area of the area information is less than or equal to the standard black area, the light-emitting module to be tested is determined to belong to the first group of light-emitting modules; when the measured black area of the area information is greater than the standard black area, the light-emitting module to be tested is determined to belong to the second group of light-emitting modules.

8. The manufacturing method of the electronic device as claimed in claim 7,
wherein obtaining the measured black area of the area information based on the second image comprises:
performing dilation on the second white portion of the second image to obtain a third image, wherein the third image comprises a third white portion; and
calculating an area difference between the third white portion of the third image and the second white portion of the second image to obtain the measured black area.

9. The manufacturing method of the electronic device as claimed in claim 2, wherein the area condition comprises being less than or equal to an area standard deviation threshold, and the area information comprises a measured area standard deviation.

10. The manufacturing method of the electronic device as claimed in claim 9, wherein
performing the image processing further comprises:
calculating areas of a plurality of white spots of the first white portion to obtain the measured area standard deviation; and
comparing the area condition with the area information of the light-emitting module to be tested comprises:
when the measured area standard deviation of the area information is less than or equal to the area standard deviation threshold, the light-emitting module to be tested is determined to belong to the first group of light-emitting modules; when the measured area standard deviation of the area information is greater than the area standard deviation threshold, the light-emitting module to be tested is determined to belong to the second group of light-emitting modules.

11. The manufacturing method of the electronic device as claimed in claim 2, wherein the area condition comprises being less than or equal to a standard white area, and the area information comprises a measured white area.

12. The manufacturing method of the electronic device as claimed in claim 11, wherein
performing the image processing further comprises:
performing erosion on the first image to obtain a fourth image of the area information, wherein the fourth image comprises a fourth black portion;
obtaining a measured white area of the area information based on the fourth black portion of the fourth image; and
comparing the area condition with the area information of the light-emitting module to be tested comprises:
when the measured white area of the area information is less than or equal to the standard white area, the light-emitting module to be tested is determined to belong to the first group of light-emitting modules, when the measured white area of the area information is greater than the standard white area, the light-emitting module to be tested is determined to belong to the second group of light-emitting modules.

13. The manufacturing method of the electronic device as claimed in claim 1, wherein after determining that the light-emitting module to be tested belongs to the second group of light-emitting modules, the manufacturing method further comprising providing a display screen to display a difference position of the light-emitting module to be tested that does not meet the area condition.

14. The manufacturing method of the electronic device as claimed in claim 2, wherein storing the area condition comprises storing a first area condition and a second area condition, and the manufacturing method comprises:
obtaining a first area information and a second area information by calculating the first image;
comparing the first area condition with the first area information of the light-emitting module to be tested; and
comparing the second area condition with the second area information of the light-emitting module to be tested, wherein the light-emitting module to be tested with the first area information meeting the first area condition and with the second area information meeting the second area condition belongs to the first group of light-emitting modules.

15. A detection device used to detect a light-emitting module to be tested, comprising:
an image-capturing module configured to capture an initial image of the light-emitting module to be tested;
a storage module configured to store an area condition; and
a processing module configured to receive the initial image of the light-emitting module to be tested captured by the image-capturing module, perform image processing on the initial image to obtain area information, and compare the area condition with the area information to obtain a comparison result to determine whether the light-emitting module to be tested belongs to a first group of light-emitting modules that meet the area condition or a second group of light-emitting modules that do not meet the area condition.

16. The detection device as claimed in claim 15, further comprising a control module configured to light up the light-emitting module to be tested.

17. The detection device as claimed in claim 15, further comprising a control module configured to activate the image-capturing module to capture the initial image of the light-emitting module to be tested.

18. The detection device as claimed in claim 15, further comprising a control module and a display device, wherein the control module is configured to receive the comparison result and transmit the comparison result to the display device.

19. The detection device as claimed in claim 18, wherein the display device is configured to provide a display screen to display the difference position of the light-emitting module to be tested of the second group of light-emitting modules that do not meet the area condition.

20. The detection device as claimed in claim 15, further comprising a control module, wherein the control module sequentially performs the following steps according to a preset process: lighting up the light-emitting module to be tested; activating the image-capturing module to capture the initial image of the light-emitting module to be tested; receiving the initial image; performing the image processing on the initial image to obtain the area information; and comparing the area condition with the area information to determine whether the light-emitting module to be tested belongs to the first group of light-emitting modules or the second group of light-emitting modules.
